(19) United States
(12) Patent Application Publication
(10) Pub. No.: US 2026/0123509 A1
(43) Pub. Date: Apr. 30, 2026

(54) HYBRID BONDING STRUCTURE WITH THERMAL DISSIPATION

(71) Applicant: International Business Machines Corporation, Armonk, NY (US)

(72) Inventors: Sarabjot Singh, Albany, NY (US); Ruilong Xie, Niskayuna, NY (US); Tao Li, Slingerlands, NY (US); Qianwen Chen, Fort Collins, CO (US); Joshua Mark Rubin, Albany, NY (US)

(21) Appl. No.: 18/930,394

(22) Filed: Oct. 29, 2024

(51) Int. Cl. H01L 23/00

(52) U.S. Cl. CPC H10W 72/90; H10W 72/953; H10W 72/965; H10W 72/967; H10W 80/312; H10W 80/327; H10W 90/794; H10W 99/00

(57) ABSTRACT

A hybrid bonded structure is provided which has a hybrid bonding area which has good bonding properties and heat dissipation. The hybrid bonding area includes a bonding dielectric containing region for providing high bond strength and a thermal conductive material containing region for dissipating heat.

### BACKGROUND

The present application relates to semiconductor technology, and more particularly to a hybrid bonded structure which contains a hybrid bonded area including a bonding dielectric containing region for high bond strength and a thermal conductive material containing region for dissipating heat.

Hybrid bonding generally refers to a 3D packing technique to connect semiconductor builds. Conventional hybrid bonding forms connections of semiconductor structures through metal bond pads which are embedded in a dielectric layer at a bond interface on each semiconductor structure that is being bonded. The dielectric layer at the bonding interface includes, but is not necessarily limited to, a bonding dielectric material such as, for example, TEOS, SiO₂, SiCN, and/or SiCOH. The metal bond pads embedded in the dielectric surfaces most commonly include, but are not necessarily limited to, copper (Cu). As part of the hybrid bonding process, the aforementioned dielectric materials go through an activation process, including but not necessarily limited to, O₂/N₂ plasma activation followed by a de-ionized water rinsing. Such activation process creates surface dangling bonds through hydroxylation of dielectric surfaces. Hybrid bonding process itself includes alignment to control the overlay of metal pads and to ensure electrical continuity between semiconductor build undergoing hybrid bonding process, mating of dielectric/metal pad surfaces, annealing under a set pressure. The anneal process of the mated semiconductor builds ensures formation of covalent bonds between the dangling bonds across the dielectric surfaces of opposing semiconductor builds, as well as reflow (melting and joining) of the metal pads between the surfaces of opposing semiconductor builds to ensure electrical conductivity. The covalent bonds formed between the dielectric surfaces, and the joining of metal pads as a result of reflow process ensures that hybrid bonding interfaces joins two semiconductor builds and also ensures that there is electrical continuity between them.

### SUMMARY

A hybrid bonded structure is provided which has a hybrid bonding area which has good bonding properties and heat dissipation. Notably, the hybrid bonding area includes a bonding dielectric containing region for providing high bond strength and a thermal conductive material containing region for dissipating heat.

In one embodiment of the present application, a structure is provided that includes a hybrid bonding area located above a frontside back-end-of-the-line (BEOL) structure. In this embodiment, the hybrid bonding area includes a bonding dielectric containing region and a thermal conductive material containing region.

In a further embodiment of the present application, the structure includes a hybrid bonding area located above a frontside BEOL structure. In this embodiment, the hybrid bonding area includes a hybrid bonding interface located between a first bonding dielectric material containing portion and a second bonding dielectric material containing portion, and between a first thermal and electrically conductive cap of a first thermal conductive material containing portion and a second thermal and electrically conductive cap of a second thermal conductive material containing portion.

### BRIEF DESCRIPTION OF THE DRAWINGS

FIG. 1 is a cross sectional view of a first exemplary structure that can be employed in the present application, the first exemplary structure including a semiconductor substrate, a device layer and a frontside BEOL structure.

FIG. 2 is a cross sectional view of the first exemplary structure of FIG. 1 after forming a first bonding dielectric layer on the frontside BEOL structure.

FIG. 3 is a cross sectional view of the first exemplary structure of FIG. 2 after patterning the first bonding dielectric layer to provide a first bonding dielectric material containing portion on the frontside BEOL structure.

FIG. 4 is a cross sectional view of the first exemplary structure of FIG. 3 after forming a first thermal conductive material containing portion laterally adjacent to the first bonding dielectric material containing portion and on the frontside BEOL structure.

FIG. 5 is a cross sectional view of the first exemplary structure of FIG. 4 after aligning a second exemplary structure over the first exemplary structure, the second exemplary structure including a second bonding dielectric material containing portion and a second thermal conductive material containing portion located on a carrier wafer.

FIG. 6 is a cross sectional view of the first exemplary structure and the second exemplary structure after performing a hybrid bonding process.

FIG. 7 is a cross sectional view of the hybrid bonded structure of FIG. 6 after removing the semiconductor substrate.

FIG. 8 is a cross sectional view of the hybrid bonded structure of FIG. 7 after forming a backside BEOL structure on a physically exposed surface of the device layer.

FIG. 9 is a cross sectional view of the first exemplary structure of FIG. 4 after forming first electrically conductive structures in the first bonding dielectric material containing portion and the first thermal conductive material containing portion.

FIG. 10 is a cross sectional of a hybrid bonded structure that includes hybrid bonding the first exemplary structure of FIG. 9 to a second exemplary structure that includes a second bonding dielectric material containing portion and a second thermal conductive material containing portion located on a carrier wafer, each of the second bonding dielectric material containing portion and the thermal conductive material containing portion contains second electrically conductive structures formed therein.

FIG. 11 is a cross sectional view of the first exemplary structure of FIG. 4 after recessing the first thermal conductive material containing portion to provide a first thermal conductive material containing base, and forming a first thermal and electrically conductive material containing cap on the first thermal conductive material containing base.

FIG. 12 is a cross sectional of a hybrid bonded structure that includes hybrid bonding the first exemplary structure of FIG. 11 to a second exemplary structure that includes a second bonding dielectric material containing portion and a second thermal conductive material containing portion located on a carrier wafer in which the second thermal conductive material containing portion includes a second thermal and electrically conductive material containing cap located on a second thermal conductive material containing base.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

The terms substantially, substantially similar, about, or any other term denoting functionally equivalent similarities refer to instances in which the difference in length, height, or orientation convey no practical difference between the definite recitation (e.g., the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

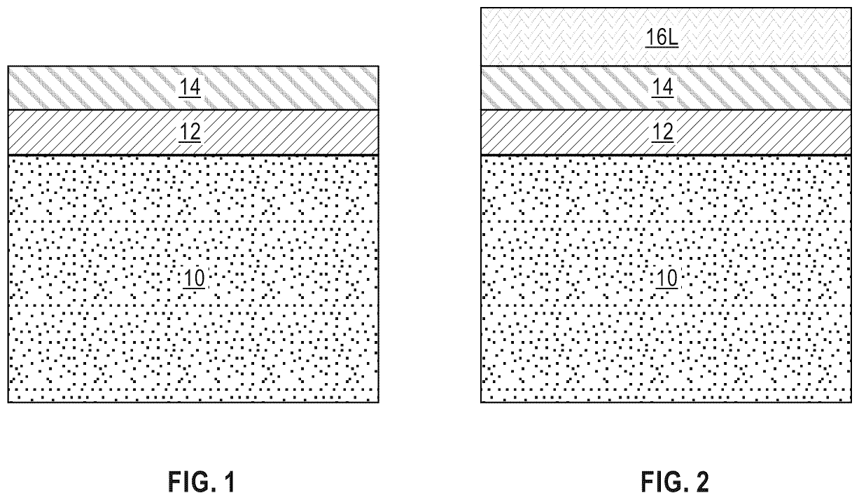

Referring first to FIG. 1, there illustrated a first exemplary structure that can be employed in the present application. The first exemplary structure illustrated in FIG. 1 includes a semiconductor substrate 10, a device layer 12 and a frontside BEOL structure 14. The semiconductor substrate 10 includes at least a semiconductor device layer. The semiconductor device layer is an uppermost portion of the semiconductor substrate 10 in which at least one semiconductor device such as, for example, a transistor, will be formed thereon. The semiconductor substrate 10 can also include a semiconductor base layer and/or an etch stop layer. In one example, the semiconductor substrate 10 can include from bottom to top, a semiconductor base layer, an etch stop layer and a semiconductor device layer. The semiconductor base layer of the semiconductor substrate 10 is composed of a first semiconductor material, and the semiconductor device layer of the semiconductor substrate 10 is composed of a second semiconductor material. As used throughout the present application, the term “semiconductor material” denotes a material that has semiconducting properties. Examples of semiconductor materials that can be used in the present application include, but are not limited to, silicon (Si), a silicon germanium (SiGe) alloy, a silicon germanium carbide (SiGeC) alloy, germanium (Ge), III/V compound semiconductors or II/VI compound semiconductors. The second semiconductor material that provides the semiconductor device layer can be compositionally the same as, or compositionally different from, the first semiconductor material that provides the semiconductor base layer. In some embodiments of the present application, the etch stop layer of the semiconductor substrate 10 can be composed of a dielectric material such as, for example, silicon dioxide and/or boron nitride. In other embodiments of the present application, the etch stop layer of the semiconductor substrate 10 is composed of a third semiconductor material that is compositionally different from the first semiconductor material that provides the semiconductor base layer and the second semiconductor material that provides the semiconductor device layer. In one example, the semiconductor base layer is composed of silicon, the etch stop layer is composed of silicon dioxide, and the semiconductor device layer is composed of silicon. In another example, the semiconductor base layer is composed of silicon, the etch stop layer is composed of silicon germanium, and the semiconductor device layer is composed of silicon.

The device layer 12 (which can also be referred to herein as a front-end-of-the-line (FEOL) level) includes one or more semiconductor devices, such as, for example, transistors, capacitors, resistors or any combination thereof located on semiconductor substrate 10. In one embodiment, the one or more semiconductor devices include at least one transistor. A transistor (or field effect transistor (FET)) includes a source region, a drain region, a semiconductor channel region located between the source region and the drain region, and a gate structure located above the semiconductor channel region. Collectively, the source region and the drain region can be referred to as a source/drain region. The gate structure includes a gate dielectric and a gate electrode. In the present application, and when a transistor is present in the device layer 12, the transistor can be a planar transistor, or a non-planar transistor including, but not limited to, a FinFET, a nanosheet transistor, a nanowire transistor, a fork sheet transistor, or a FET stack including at least one transistor stack above another transistor. The one or more semiconductor devices can be formed utilizing conventional semiconductor devices processing that is well known to those skilled in the art. For example, nanosheet transistors can be formed utilizing any well-known nanosheet transistor formation process.

In embodiments of the present application, the device layer 12 can include a high performance device region which includes semiconductor devices that can operate at a high temperature. This high performance device region can be located adjacent to other types of device regions such as for example, a device region in which the semiconductor devices operate at a lower temperature than the semiconductor devices that are present in the high performance device region.

The device layer 12 can also include an interlayer dielectric (ILD) layer which embeds at least a portion of the one or more semiconductor devices. The ILD layer includes an ILD material including, for example, silicon oxide, silicon nitride, undoped silicate glass (USG), fluorosilicate glass (FSG), borophosphosilicate glass (BPSG), a spin-on low-k dielectric layer, a chemical vapor deposition (CVD) low-k dielectric layer or any combination thereof. The term “low-k” as used throughout the present application denotes a dielectric material that has a dielectric constant of less than 4.0. All dielectric constants mentioned herein are measured in a vacuum unless otherwise stated.

Although not illustrated in the drawings, a middle-of-the-line (MOL) level is typically located between the device layer 12 and the frontside BEOL structure 14. The MOL level includes frontside contact structures (e.g., frontside gate contact structure and/or frontside source/drain contact structures) embedded in one or more ILD layers. The one or more ILD layers of the MOL level are composed of an ILD material including those mentioned above. The frontside contact structures are composed of at least a contact conductor material. The contact conductor material can include, for example, a silicide liner, such as Ni, Pt, NiPt, an adhesion metal liner, such as TiN, and conductive metals such as W, Cu, Al, Co, Ru, Mo, Os, Ir, Rh, or an alloy thereof. The frontside contact structures can also include one or more contact liners (not shown). In one or more embodiments, the contact liner (not shown) can include a diffusion barrier material. Exemplary diffusion barrier materials include, but are not limited to, Ti, Ta, Ni, Co, Pt, W, Ru, TiN, TaN, WN, WC, an alloy thereof, or a stack thereof such as Ti/TiN and Ti/WC. In one or more embodiments in which a contact liner is present, the contact liner (not shown) can include a silicide liner, such as Ti, Ni, NiPt, etc., and a diffusion barrier material, as defined above. The MOL level can be formed utilizing MOL processing techniques that are well known to those skilled in the art.

The frontside BEOL structure 14 is composed of an interconnect dielectric region having frontside metal wiring embedded therein; the frontside metal wiring present in the frontside BEOL structure 14 is typically signal wires. The interconnect dielectric region includes one or more interconnect dielectric material layers. The interconnect dielectric material layers can be composed of at least one of the ILD materials mentioned above. The frontside metal wiring can be in the form of metal lines, metal vias, a metal via/metal line combination or any combinations thereof. The frontside metal wiring is composed of an electrically conductive metal or an electrically conductive metal alloy. Exemplary electrically conductive metals include, but are not limited to, Cu, W, Al, Co, or Ru. An exemplary electrically conductive metal alloy is a Cu—Al alloy. The frontside BEOL structure 14 can be formed utilizing any well-known BEOL process including a damascene process or a subtractive metal etch process.

Referring now to FIG. 2, there is illustrated the first exemplary structure of FIG. 1 after forming a first bonding dielectric layer 16L on the frontside BEOL structure 14. The first bonding dielectric layer 16L is composed of a first bonding dielectric such as, for example, tetraethyl orthosilicate (TEOS), SiO₂, silicon carbon nitride (SiCN) and/or carbon-doped silicon oxide (SiCOH). The first bonding dielectric that provides the first bonding dielectric layer 16L is formed by a deposition process such as, for example, chemical vapor deposition (CVD), plasma enhanced chemical vapor deposition (PECVD), evaporation or spin-on coating. Although not required, a planarization process such as, for example, chemical mechanical planarization (CMP) can follow the deposition of the first bonding dielectric. In some embodiments, the first bonding dielectric layer 16L can be formed in direct physical contact with the frontside BEOL structure 14. In other embodiments, one or more additional layers (typically dielectric layers) can be formed between the first bonding dielectric layer 16L and the frontside BEOL structure 14.

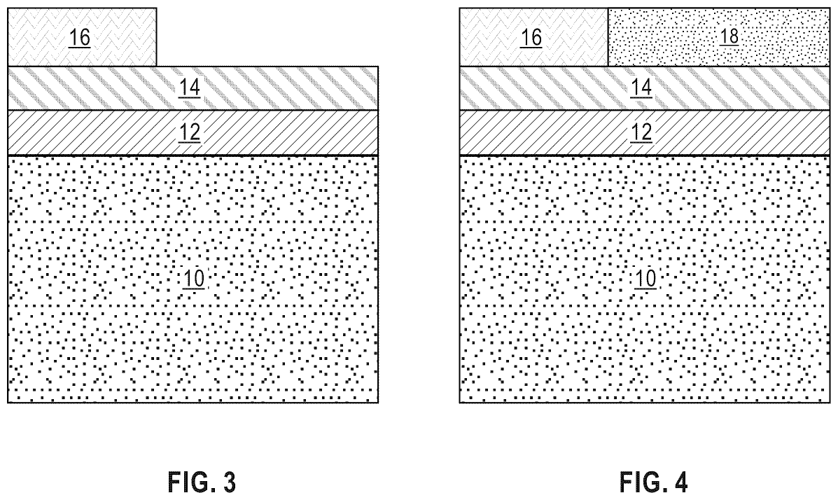

Referring now to FIG. 3, there is illustrated the first exemplary structure of FIG. 2 after patterning the first bonding dielectric layer 16L to provide a first bonding dielectric material containing portion 16 on the frontside BEOL structure 14. The patterning of the first bonding dielectric layer 16L can include lithographic patterning. Lithographic patterning includes forming a photoresist material on a layer/multilayered stack that needs to be patterned, exposing the as deposited photoresist material to a desired pattern of irradiation, developing the photoresist material and transferring the pattern from the developed photoresist material into the layer/multilayered stack that needs to be patterned, the transferring of the pattern can include one or more etching processes. The one or more etching processes can include dry etching and/or wet etching. Dry etching can include reactive ion etching (RIE), plasma etching or ion beam etching. Wet etching can include the use of a chemical etchant that is selective in removing physically exposed portions of the layer/multilayered stack that needs to be patterned. The photoresist material is removed after the pattern transfer process utilizing a material removal process that is selective in removing the photoresist material. In the present application, the first bonding dielectric layer 16L is removed from the high performance device region mentioned above, while the first bonding dielectric material containing portion 16 remains on the other device regions mentioned above.

Referring now to FIG. 4, there is illustrated the first exemplary structure of FIG. 3 after forming a first thermal conductive material containing portion 18 laterally adjacent to the first bonding dielectric material containing portion 16 and on the frontside BEOL structure 14 (the first thermal conductive material containing portion 18 is typically formed in the high performance device region mentioned above). In the illustrated embodiment of the present application, the first thermal conductive material containing portion 18 has a sidewall that is in direct physical contact with a sidewall of the first bonding dielectric material containing portion 16. In other embodiments (not illustrated), the first thermal conductive material containing portion 18 can be formed spaced apart from the first bonding dielectric material containing portion 16. In such an embodiment, a non-bonding dielectric material can be formed between the first bonding dielectric material containing portion 16 and the first thermal conductive material containing portion 18. In the illustrated embodiment, the first thermal conductive material containing portion 18 has a topmost surface that is substantially coplanar with a topmost surface of the first bonding dielectric material containing portion 16. In embodiments, the first thermal conductive material containing portion 18 is formed in direct physical contact with a physically exposed surface of the frontside BEOL structure 14. In other embodiments, the first thermal conductive material containing portion 18 is formed on one or more additional layers mentioned above that can be located between the first bonding dielectric layer 16L and the frontside BEOL structure 14.

The first thermal conductive material containing portion 18 is composed of thermal conductive material which is used in the present application for dissipating heat from the structure. Typically, the first thermal conductive material containing portion 18 dissipates heat generated by the various devices (including frontside BEOL structure 14, and transistors and other types of semiconductor device that are present in the device layer 12) present in the structure. In some embodiments, the thermal conductive material that provides the first thermal conductive material containing portion 18 can be a dielectric material (i.e., an electrical insulator) such as, for example, aluminum nitride. It is noted that when a dielectric material is employed as the thermal conductive material it is compositionally different from the first bonding dielectric material mentioned above. In other embodiments of the present application, the thermal conductive material that provides the first thermal conductive material containing portion 18 can be composed of a thermal and electrically conductive material including a metal and/or a metal alloy. Examples of thermal and electrically conductive materials include, but are not limited to, Cu, W, Al, Co, Ru or alloys thereof. The first thermal conductive material containing portion 18 can be formed by deposition of the thermal conductive material, followed by a planarization process. The thermal conductive material used in forming the first thermal conductive material containing portion 18 can be deposited by, for example, CVD, PECVD, physical vapor deposition (PVD) or atomic layer deposition (ALD). Sputtering and plating can also be used when the thermal conductive material is composed of a thermal and electrically conductive material. The first thermal conductive material containing portion 18 can be a singled layered structure or a multilayered layer structure.

While the present application describes and illustrates the formation of the first bonding dielectric material containing portion 16 prior to forming the first thermal conductive material containing portion 18, the present application works when the first thermal conductive material containing portion 18 is formed prior to forming the first bonding dielectric material containing portion 16. In such an embodiment, a layer of thermal conductive material would be formed (by a deposition process) on the frontside BEOL structure 14, the layer of thermal conductive material would then be patterned to provide the first thermal conductive material containing portion 18, and thereafter the first bonding dielectric material containing portion 16 would be formed by deposition, followed by a planarization process.

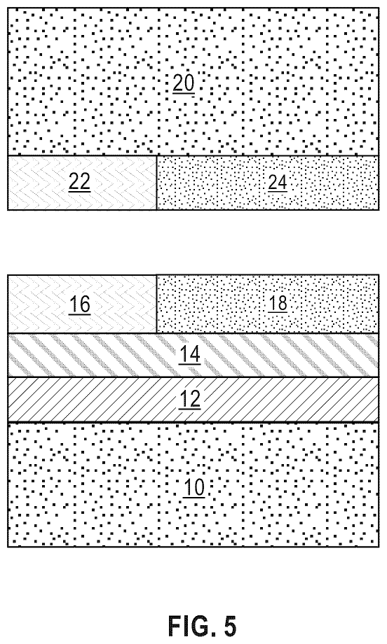

Referring now to FIG. 5, there is illustrated the first exemplary structure of FIG. 4 after aligning a second exemplary structure over the first exemplary structure, the second exemplary structure including a second bonding dielectric material containing portion 22 and a second thermal conductive material containing portion 24 located on a carrier wafer 20. Note that the second exemplary structure has a same pattern as the first exemplary structure. While the present application illustrates aligning of the second exemplary structure over the first exemplary structure, the present application works when the first exemplary structure is aligned over the second exemplary structure.

Carrier wafer 20 is composed of a semiconductor material as mentioned above for semiconductor substrate 10. The second bonding dielectric material containing portion 22 is composed of a second bonding dielectric. The second bonding dielectric can include one of the first bonding dielectrics mentioned above for the first bonding dielectric layer 16L. The second bonding dielectric that provides the second bonding dielectric material containing portion 22 can be compositionally the same as, or compositionally different from, the first bonding dielectric that provides the first bonding dielectric layer 16L. The second thermal conductive material containing portion 24 is composed of a thermal conductive material (i.e., dielectric material and/or thermal and electrically conductive material) as mentioned above for the first thermal conductive material containing portion 18. The second bonding dielectric material containing portion 22 and the second thermal conductive material containing portion 24 can be formed utilizing one of the techniques mentioned above for forming the first bonding dielectric material containing portion 16 and the first thermal conductive material containing portion 18.

In the present application, the aligning includes flipping one of the first exemplary structure or the second exemplary structure 180° such that the bonding dielectric material containing portions and the thermal conductive material containing portions of the two exemplary structures face each other as is shown in FIG. 5. The aligning continues by positioning the bonding dielectric material containing portion of one of the exemplary structures over the bonding dielectric material containing portion of the other exemplary structure and by positioning the thermal conductive material containing portion of one of the exemplary structures over the thermal conductive material containing portion of the other exemplary structure. Notably, and in the illustrated embodiment, the second bonding dielectric material containing portion 22 is positioned over the first bonding dielectric material containing portion 16 and the second thermal conductive material containing portion 24 is positioned over the first thermal conductive material containing portion 18. The bonding dielectric material containing portions and the thermal conductive material containing portions of the two exemplary structures can be perfectly aligned with each other, or a slight misalignment can exist between the bonding dielectric material containing portions and the thermal conductive material containing portions of the two exemplary structures. The slight misalignment must however include some overlap between the bonding dielectric material containing portions and the thermal conductive material containing portions of the two exemplary structures.

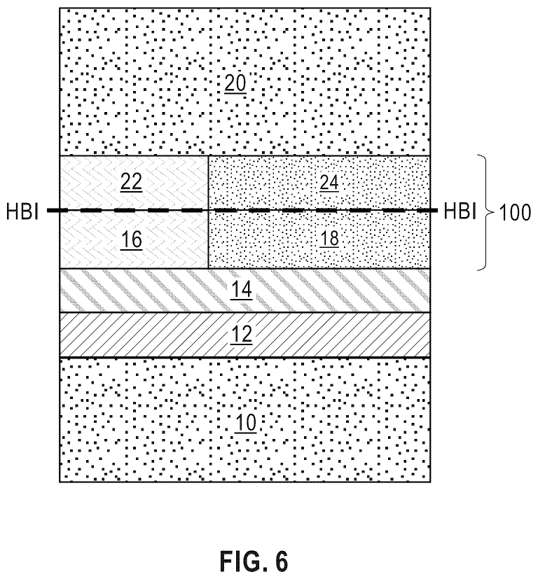

Referring now to FIG. 6, there is illustrated the first exemplary structure and the second exemplary structure after performing a hybrid bonding process. The hybrid bonding process forms a hybrid bonding interface, HBI, between the hybrid bonded first and second exemplary structures. Notably and in this embodiment, the HBI is formed between the second bonding dielectric material containing portion 22 and the first bonding dielectric material containing portion 16 and between the second thermal conductive material containing portion 24 and the first thermal conductive material containing portion 18. The area including the hybrid bonded first and second bonding dielectric portions and the hybrid bonded first and second thermal conductive material containing portions can be referred to as a hybrid bonding area 100. The hybrid bonding area 100 is located above the frontside BEOL structure 14. In this embodiment of the present application, the hybrid bonding area 100 includes HBI and the HBI is present between two thermal conductive material containing portions (i.e., the first thermal conductive material containing portion 18 and the second thermal conductive material containing portion 24) and between two bonding dielectric material containing portions (i.e., the first bonding dielectric material containing portion 16 and the second bonding dielectric material containing portion 22).

In this embodiment, the HBI includes a first hybrid bond between the second bonding dielectric material containing portion 22 and the first bonding dielectric material containing portion 16, and a second hybrid bond between the second thermal conductive material containing portion 24 and the first thermal conductive material containing portion 18. In this embodiment, the first hybrid bond is a dielectric-to-dielectric bond. The first hybrid bond can be a covalent bond between the bonding dielectrics that provide the second bonding dielectric material containing portion 22 and the first bonding dielectric material containing portion 16. The second hybrid bond can be a dielectric-to-dielectric bond (when the first thermal conductive material containing portion 18 and the second thermal conductive material containing portion are both composed of a dielectric material that is thermal conductive) or a metal-to-metal bond (when the first thermal conductive material containing portion 18 and the second thermal conductive material containing portion 24 are both composed of a thermal and electrically conductive material). In some embodiments, the second hybrid bond includes an aluminum nitride-to-aluminum nitride bond.

Hybrid bonding includes bringing the aligned first and second exemplary structures into intimate contact with each other. When brought into intimate contact, the second bonding dielectric material containing portion 22 is brought into direct physical contact with the first bonding dielectric material containing portion 16 and the second thermal conductive material containing portion 24 is brought into direct physical contact with the first thermal conductive material containing portion 18. The bringing the aligned first and second exemplary structures into intimate contact with each other can include the application of an external force which may or may not remain during a heating (i.e., annealing) step of the hybrid bonding process. Hybrid bonding continues by heating the two intimately contacted exemplary structures. The heating of the hybrid bonding provides the HBI mentioned above. Heating can be performed from room temperature (i.e., 20° C.-25° C.) typically up to 450° C.; temperatures greater than 450° C. can also be used in the present application. Heat is typically performed in an inert ambient such as, for example, He, Ar, Ne or mixtures thereof. After hybrid bonding, the temperature can be lowered back to room temperature. The hybrid bonding can also include an activation process including but not necessarily limited to, O₂/N₂ plasma activation followed by a de-ionized water rinsing. Such activation process creates surface dangling bonds through hydroxylation of dielectric surfaces. Notably, dangling bonds and covalent bonds can be created on the surface of the second bonding dielectric material containing portion 22 and the first bonding dielectric material containing portion 16 and, in some embodiments, on the surface of the second thermal conductive material containing portion 24 and the first thermal conductive material containing portion 18.

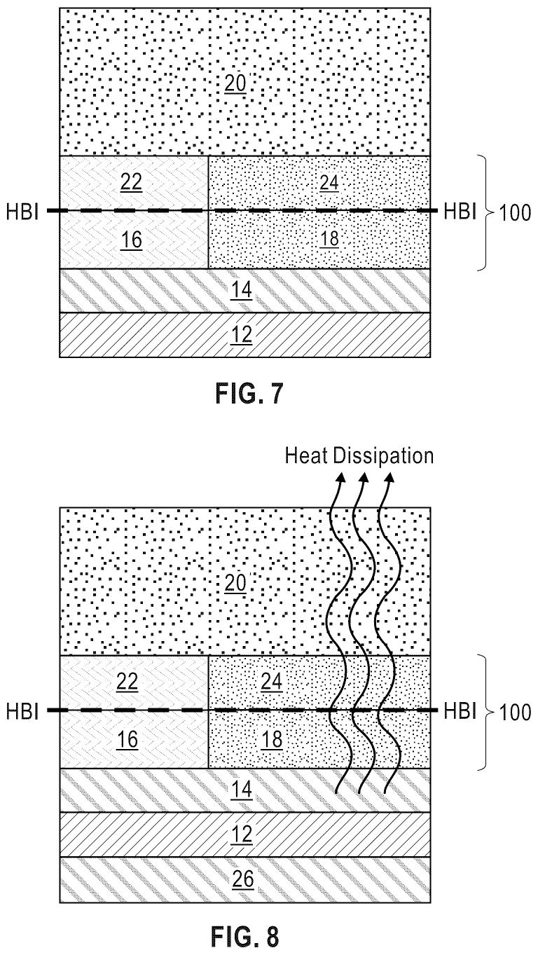

Referring now to FIG. 7, there is illustrated the hybrid bonded structure of FIG. 6 after removing the semiconductor substrate 10. The removal of the semiconductor substrate 10 can include one or more material removal processes. In some embodiments and as is illustrated in FIG. 7, the one of more material removal processes can remove an entirety of the semiconductor substrate 10 such that a surface of the device layer 12 (opposite the surface that contains the frontside BEOL structure 14) is physically exposed. In other embodiments not illustrated, the one of more material removal processes partially remove the semiconductor substrate 10 leaving behind a thin semiconductor material layer of the semiconductor substrate 10 on a backside of the device layer 12. The one or more material removal processes can include an etching process, a planarization process such as, for example, CMP or a combination of etching and planarization. Prior to the removing the semiconductor substrate 10, the hybrid bonded structure of FIG. 6 is flipped 180° to physically expose a backside of the hybrid bonded structure. For clarity, the flipping step is not shown in the drawings. Flipping can be performed by hand or by utilizing a mechanical means such as, for example, a robot arm.

Referring now to FIG. 8, there is illustrated the hybrid bonded structure of FIG. 7 after forming a backside BEOL structure 26 on the device layer 12. Embodiments are contemplated in which the backside BEOL structure 26 is formed on a remaining semiconductor material portion of the semiconductor substrate 10. In some embodiments, at least one backside ILD layer (not shown) can be formed between the backside BEOL structure 26 and either the physical exposed surface of the device layer 12 or on a remaining semiconductor material portion of the semiconductor substrate 10. When present, the at least one backside ILD layer includes an ILD material including those mentioned previously herein. The at least one backside ILD layer can be formed by a deposition process, followed in some instances, by a planarization process.

The backside BEOL structure 26 (which can delivery power from the backside of the device) is composed of an interconnect dielectric region having backside metal wiring embedded therein. The interconnect dielectric region includes one or more interconnect dielectric material layers. The interconnect dielectric material layers can be composed of one of the ILD materials mentioned above. The backside metal wiring which can be in the form of metal lines, metal vias, a metal via/metal line combination or any combinations thereof is composed of an electrically conductive metal or an electrically conductive metal alloy, as both defined above. The backside BEOL structure 26 can be formed utilizing any well-known BEOL process including a damascene process or a subtractive metal etch process.

Notably, FIG. 8 illustrates a structure in accordance with an embodiment of the present application. The structure illustrated in FIG. 8 includes hybrid bonding area 100 located above frontside BEOL structure 14 in which the hybrid bonding area 100 includes a bonding dielectric containing region and a thermal conductive material containing region. The bonding dielectric containing region includes first bonding dielectric material containing portion 16 and second bonding dielectric material containing portion 22, and hybrid bonding interface, HBI, is located between the first bonding dielectric material containing portion 16 and the second bonding dielectric material containing portion 22. The hybrid bonding interface between the first bonding dielectric material containing portion 16 and the second bonding dielectric material containing portion 22. includes a dielectric-to-dielectric bond. The thermal conductive material containing region includes first thermal conductive material containing portion 18 and second thermal conductive material containing portion 24, and the HBI is located between the first thermal conductive material containing portion 18 and the second thermal conductive material containing portion 24. The hybrid bonding interface between the first thermal conductive material containing portion 18 and the second thermal conductive material containing portion 24 can include a dielectric-to-dielectric bond or a metal-to-metal bond.

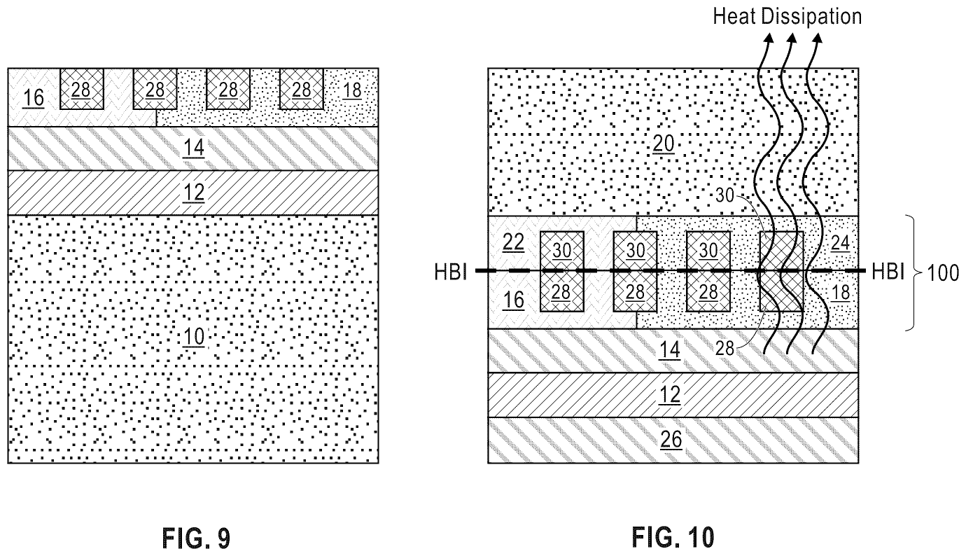

Referring now to FIG. 9, there is illustrated the first exemplary structure of FIG. 4 after forming first electrically conductive structures 28 in the first bonding dielectric material containing portion 16 and the first thermal conductive material containing portion 18. In some embodiments and as illustrated in FIG. 9, the first electrically conductive structures 28 can extend partially through the first bonding dielectric material containing portion 16 and partially through the first thermal conductive material containing portion 18. In other embodiments, the first electrically conductive structures 28 can extend completely through the first bonding dielectric material containing portion 16 and completely through the first thermal conductive material containing portion 18. While yet in other embodiments, the first electrically conductive structures 28 can extend partially through the first bonding dielectric material containing portion 16 and completely through the first thermal conductive material containing portion 18 region, or the first electrically conductive structures 28 can extend completely through the first bonding dielectric material containing portion 16 and partially through the first thermal conductive material containing portion 18. While the present application illustrates first electrically conductive structures 28 in both the first bonding dielectric material containing portion 16 and the first thermal conductive material containing portion 18, the present application works when the first electrically conductive structures 28 are formed in only one of the first bonding dielectric material containing portion 16 or the first thermal conductive material containing portion 18. While the majority of the first electrically conductive structures 28 are not shared between the first bonding dielectric material containing portion 16 and the first thermal conductive material containing portion 18, it is possible to form one of the first electrically conductive structures 28 such that a portion of the first electrically conductive structure 28 is present in the first bonding dielectric material containing portion 16 and another portion of the first electrically conductive structure 28 is present in the first thermal conductive material containing portion 18.

Each first electrically conductive structure 28 is composed of an electrically conductive metal and/or an electrically conductive metal alloy. Illustrative examples of electrically conductive metals include, but are not limited to, Cu, W, Al, Co, or Ru. An illustrative example of an electrically conductive metal alloy includes Cu—Al alloy. These electrically conductive materials can also be thermal conducting as well. Note that in embodiments in which the first thermal conductive material containing portion 18 is composed of a thermal and electrically conductive material, the electrically conductive material that provides each first electrically conductive structure 28 is compositionally different from the thermal and electrically conductive material that provides the first thermal conductive material containing portion 18.

In some embodiments not shown, a diffusion barrier liner can be present along a sidewall and bottom surface of the first electrically conductive structure 28. When present, the diffusion barrier liner is composed of a diffusion barrier material (i.e., a material that serves as a barrier to prevent a conductive material such as copper from diffusing there through). Examples of diffusion barrier materials include, but are not limited to, Ta, TaN, Ti, TiN, Ru, RuN, RuTa, RuTaN, W, or WN. In some embodiments, the diffusion barrier material can include a material stack of diffusion barrier materials. In one example, the diffusion barrier material can be composed of a stack of Ta/TaN.

The first electrically conductive structures 28 and, when present, the diffusion barrier liner can be formed by a metallization process in which openings are formed in the first bonding dielectric material containing portion 16 and/or the first thermal conductive material containing portion 18, and then a diffusion barrier layer and an electrically conductive material are separately deposition in each of the openings, and thereafter a planarization process is used to remove the diffusion barrier layer and the electrically conductive material that is formed outside of the openings. Each first electrically conductive structure 28 has a topmost surface that is substantially coplanar to a topmost surface of the first bonding dielectric material containing portion 16 and the first thermal conductive material containing portion 18.

Referring now to FIG. 10, there is illustrated a hybrid bonded structure that includes hybrid bonding the first exemplary structure of FIG. 9 to a second exemplary structure that includes a second bonding dielectric material containing portion 22 and a second thermal conductive material containing portion 24 located on a carrier wafer 20, each of the second bonding dielectric material containing portion 22 and second thermal conductive material containing portions 24 contains second electrically conductive structures 30 formed therein. It is noted that the second exemplary structure has a same pattern as the first exemplary structure.

The carrier wafer 20, the second bonding dielectric material containing portion 22, and the second thermal conductive material containing portion 24 of this embodiment are the same as described above for the embodiment illustrated in FIG. 5. The second electrically conductive structures 30 include an electrically conductive metal or electrically conductive metal alloy as mentioned above for the first electrically conductive structures 28. The electrically conductive material that provides the second electrically conductive structures 30 can be compositionally the same as, or compositionally different from, the electrically conductive material that provides the first electrically conductive structures 28. When a thermal conductive metal is present in the second thermal conductive material containing portion 24, the electrically conductive material that provides the second electrically conductive structures 30 are compositionally different than the thermal conductive material that provides the second thermal conductive material containing portion 24. The second electrically conductive structures 30 can be formed utilizing a metallization process as discussed above for forming the first electrically conductive structures 28. A diffusion barrier liner can optionally be present along a sidewall and bottom surface of the second electrically conductive structures 30.

The hybrid bonded structure is formed by alignment (as described above in regard to FIG. 5), intimately contacting the aligned first and second exemplary structures (as described above in regard to FIG. 6), heating the aligned and intimately contact structures (as described above in regard to FIG. 6). The heating step forms an HBI as shown in FIG. 10. Notably, the HBI is formed between the second bonding dielectric material containing portion 22 and the first bonding dielectric material containing portion 16, between the second thermal conductive material containing portion 24 and the first thermal conductive material containing portion 18, and between each first electrically conductive structure 28 and each second electrically conductive structure 30 that are bonded together. The area including the hybrid bonded first and second bonding dielectric material containing portions and the hybrid bonded first and second thermal conductive material containing portions can be referred to as a hybrid bonding area 100. In this embodiment, the hybrid bonded area 100 also includes the hybrid bonded first and second electrically conductive structures. The hybrid bonded area 100 is located above the frontside BEOL structure 14. In this embodiment of the present application, the hybrid bonding area 100 includes HBI and the HBI is present between two thermal conductive material containing portions (i.e., the first thermal conductive material containing portion 18 and the second thermal conductive material containing portion 24), between two bonding dielectric material containing portions (i.e., the first bonding dielectric material containing portion 16 and the second bonding dielectric material containing portion 22) and between each pair of bonded electrically conductive structures (i.e., each bonded first electrically conductive structure 28/second electrically conductive structure 30 pair).

In this embodiment, the HBI includes a first hybrid bond between the second bonding dielectric material containing portion 22 and the first bonding dielectric material containing portion 16, a second hybrid bond between the second thermal conductive material containing portion 24 and the first thermal conductive material containing portion 18, and a metal-to-metal bond between each first electrically conductive structure 28/second electrically conductive structure 30 bonded pair. In this embodiment, the first bond located at the HBI is a dielectric-to-dielectric bond. The first hybrid bond can be a covalent bond between the bonding dielectrics that provide the second bonding dielectric material containing portion 22 and the first bonding dielectric material containing portion 16. The second hybrid bond can be a dielectric-to-dielectric bond (when the first thermal conductive material containing portion 18 and the second thermal conductive material containing portion 24 are both composed of a dielectric material that is thermal conductive) or a metal-to-metal bond (when the first thermal conductive material containing portion 18 and the second thermal conductive material containing portion 24 are both composed of a thermal and electrically conductive material). In some embodiments, the second hybrid bond includes an aluminum nitride-to-aluminum nitride bond. The third hybrid bond includes a metal-to-metal bond (e.g., a Cu—Cu bond).

After hybrid bonding, the semiconductor substrate 10 can be entirely or partially removed, as described above in regard to FIG. 7. One or more backside ILD layers as described above can be optionally formed, and thereafter backside BEOL structure 26 can be formed. The backside BEOL structure 26 illustrated in FIG. 10 is the same as the backside BEOL structure 26 shown in FIG. 8. Thus the materials and processing mentioned above for backside BEOL structure 26 shown in FIG. 8 apply here for the backside BEOL structure 26 shown in FIG. 10.

Notably, FIG. 10 illustrates a structure in accordance with another embodiment of the present application. The structure illustrated in FIG. 10 includes hybrid bonding area 100 located above frontside BEOL structure 14 in which the hybrid bonding area 100 includes a bonding dielectric containing region and a thermal conductive material containing region. The bonding dielectric containing region includes first bonding dielectric material containing portion 16 and second bonding dielectric material containing portion 22, and hybrid bonding interface, HBI, is located between the first bonding dielectric material containing portion 16 and the second bonding dielectric material containing portion 22. The HBI between the first bonding dielectric material containing portion 16 and the second bonding dielectric material containing portion 22. includes a dielectric-to-dielectric bond. The thermal conductive material containing region includes first thermal conductive material containing portion 18 and second thermal conductive material containing portion 24, and the HBI is located between the first thermal conductive material containing portion 18 and the second thermal conductive material containing portion 24. The hybrid bonding interface between the first thermal conductive material containing portion 18 and the second thermal conductive material containing portion 24 can include a dielectric-to-dielectric bond or a metal-to-metal bond. The structure illustrated in FIG. 10 further includes at least one hybrid bonded electrically conductive structure located in at least one of the bonding dielectric containing region and the thermal conductive material containing region. The at least one hybrid bonded electrically conductive structure includes first electrically conductive structure 28 and second electrically conductive structure 30. As is illustrated in FIG. 10, the HBI is located between each first electrically conductive structure/second electrically conductive structure hybrid bonded pair.

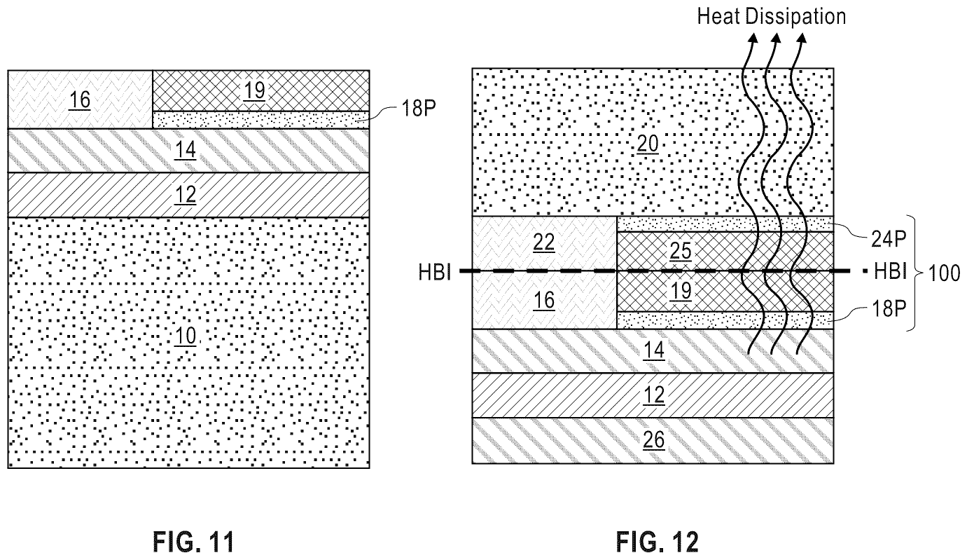

Referring now to FIG. 11, there is illustrated the first exemplary structure of FIG. 4 after recessing the first thermal conductive material containing portion 18 to provide a first thermal conductive material containing base 18P, and forming a first thermal and electrically conductive cap 19 on the a first thermal conductive material containing base 18P. Collectively, the first thermal conductive material containing base 18P and the first thermal and electrically conductive cap 19 provides a first thermal conductive material containing portion. The recessing of the first thermal conductive material containing portion 18 includes a recess etch that is selective in partially removing the first thermal conductive material containing portion 18. The recessed etch does not etch way any portion of the first bonding dielectric material containing portion 16. In this embodiment of the present application, the first thermal conductive material containing base 18P has a sidewall that may, or may not, be in direct physical contact with a sidewall of the first bonding dielectric material containing portion 16 and a topmost surface that is vertically off-set and located beneath a topmost surface of the first bonding dielectric material containing portion 16. Stated in other terms, the vertical thickness of the first bonding dielectric material containing portion 16 is greater than a vertical thickness of the first thermal conductive material containing base 18P. In embodiments, the first thermal conductive material containing portion 18 and thus the first thermal conductive material containing base 18P is composed of aluminum nitride (AlN). In such embodiments, the first thermal conductive material containing base 18P composed of AlN can prevent shorts.

The first thermal and electrically conductive cap 19, which is formed on top of the first thermal conductive material containing base 16P, is composed of a thermal and electrically conductive material as described above. When the first thermal conductive material containing base 18P is composed of a thermal and electrically conductive material, then the thermal and electrically conductive material that provides the first thermal and electrically conductive cap 19 is compositionally different from the thermal and electrically conductive material that provides the first thermal conductive material containing base 18P. The first thermal and electrically conductive cap 19 can be formed by deposition of at least one electrically conductive material, followed by a planarization process. The first thermal and electrically conductive cap 19 has a sidewall that may, or may not, be in direct physical contact with a sidewall of the first bonding dielectric material containing portion 16 and a topmost surface that is substantially coplanar with a topmost surface of the first bonding dielectric material containing portion 16.

Referring now to FIG. 12, there is illustrated a hybrid bonded structure that includes hybrid bonding the first exemplary structure of FIG. 11 to a second exemplary structure that includes a second bonding dielectric material containing portion 22 and a second thermal conductive material containing portion located on a carrier wafer 20 in which the second thermal conductive material containing portion includes a second thermal and electrically conductive cap 25 located on a second thermal conductive material containing base 24P. It is noted that the second exemplary structure has a same pattern as the first exemplary structure. The carrier wafer 20 and the second bonding dielectric material containing portion 22 of this embodiment are the same as described above for the embodiment illustrated in FIG. 5. The second thermal conductive material containing base 24P is a portion of the second thermal conductive material containing portion 24 that remains after a recessed etch is performed on the second exemplary structure shown in FIG. 5.

The second thermal and electrically conductive cap 25, which is formed on top of the second thermal conductive material containing base 24P, is composed of a thermal and electrically conductive material as described above. When the second thermal conductive material containing base 24P is composed of a thermal and electrically conductive material, then the thermal and electrically conductive material that provides the second thermal and electrically conductive cap 25 is compositionally different from the thermal and electrically conductive metal that provides the second thermal conductive material containing base 24P. The second thermal and electrically conductive cap 25 can be formed by deposition of at least one electrically conductive material, followed by a planarization process. The second thermal and electrically conductive cap 25 has a sidewall that may, or may not, be in direct physical contact with a sidewall of the second bonding dielectric material containing portion 22 and a topmost surface that is substantially coplanar with a topmost surface of the second bonding dielectric material containing portion 22.

The hybrid bonded structure is formed by alignment (as described above in regard to FIG. 5), intimately contacting the aligned first and second exemplary structures (as described above in regard to FIG. 6), heating the aligned and intimately contact structures (as described above in regard to FIG. 6). The heating step forms an HBI as shown in FIG. 12. Notably, the HBI is formed between the second bonding dielectric material containing portion 22 and the first bonding dielectric material containing portion 16, and between the second thermal and electrically conductive cap 25 and the first thermal and electrically conductive cap 19. The area including the hybrid bonded first and second bonding dielectric material containing portions and the hybrid bonded first and second thermal and electrically conductive caps can be referred to as a hybrid bonding area 100. In this embodiment, the hybrid bonded area 100 further includes the first and second thermal conductive material containing bases. The hybrid bonded area 100 is located above the frontside BEOL structure 14. In this embodiment of the present application, the hybrid bonding area 100 includes HBI and the HBI is present between two bonding dielectric material containing portions (i.e., the first bonding dielectric material containing portion 16 and the second bonding dielectric material containing portion 22) and between two thermal and electrically conductive caps (i.e., first thermal and electrically conductive cap 19 and the second thermal and electrically conductive cap 25).

In this embodiment, the HBI includes a first hybrid bond between the second bonding dielectric material containing portion 22 and the first bonding dielectric material containing portion 16, and a second hybrid bond between the second thermal and electrically conductive cap 25 and the first thermal and electrically conductive cap 19. In this embodiment, the first hybrid bond located at the HBI is a dielectric-to-dielectric bond. The first hybrid bond can be a covalent bond between the bonding dielectrics that provide the second bonding dielectric material containing portion 22 and the first bonding dielectric material containing portion 16. The second hybrid bond which is also located at the HBI is a metal-to-metal bond.

After hybrid bonding, the semiconductor substrate 10 can be entirely or partially removed, as described above in regard to FIG. 7. One or more backside ILD layers are described above can be optionally formed, and thereafter backside BEOL structure 26 can be formed. The backside BEOL structure 26 illustrated in FIG. 12 is the same as the backside BEOL structure 26 shown in FIG. 8. Thus the materials and processing mentioned above for backside BEOL structure 26 shown in FIG. 8 apply here for the backside BEOL structure 26 shown in FIG. 10.

Notably, FIG. 12 illustrates a structure in accordance with another embodiment of the present application. The structure illustrated in FIG. 12 hybrid bonding area 100 located above frontside BEOL structure 14. In this embodiment, the hybrid bonding area 100 includes a hybrid bonding interface, HBI, located between first bonding dielectric material containing portion 16 and second bonding dielectric material containing portion 22, and between first thermal and electrically conductive cap 19 of a first thermal conductive material containing portion and second thermal and electrically conductive cap 25 of a second thermal conductive material containing portion. In this embodiment, first thermal conductive material containing base 18P is in contact with a surface of the first thermal and electrically conductive cap 19, and second thermal conductive material containing base 24P is in contact with a surface of the second thermal and electrically conductive cap 25.

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. A structure comprising:
a hybrid bonding area located above a frontside back-end-of-the-line (BEOL) structure, wherein the hybrid bonding area comprises a bonding dielectric containing region and a thermal conductive material containing region.

2. The structure of claim 1, wherein the bonding dielectric containing region comprises a first bonding dielectric material containing portion and a second bonding dielectric material containing portion, and wherein a hybrid bonding interface is located between the first bonding dielectric material containing portion and the second bonding dielectric material containing portion.

3. The structure of claim 2, wherein the hybrid bonding interface comprises a dielectric-to-dielectric bond.

4. The structure of claim 2, wherein the first bonding dielectric material containing portion and the second bonding dielectric material containing portion are composed of a bonding dielectric material.

5. The structure of claim 1, wherein the thermal conductive material containing region comprises a first thermal conductive material containing portion and a second thermal conductive material containing portion, and wherein a hybrid bonding interface is located between the first thermal conductive material containing portion and the second thermal conductive material containing portion.

6. The structure of claim 5, wherein the first thermal conductive material containing portion and the second thermal conductive material containing portion are composed of a dielectric material and the hybrid bonding interface comprises a dielectric-to-dielectric bond.

7. The structure of claim 5, wherein the first thermal conductive material containing portion and the second thermal conductive material containing portion are composed of a thermal and electrically conductive material and the hybrid bonding interface comprises a metal-to-metal bond.

8. The structure of claim 1, further comprising a device layer comprises one or more semiconductor devices located beneath the frontside BEOL structure.

9. The structure of claim 8, further comprising a backside BEOL structure located beneath the device layer.

10. The structure of claim 1, further comprising at least one hybrid bonded electrically conductive structure located in at least one of the bonding dielectric containing region and the thermal conductive material containing region.

11. The structure of claim 10, wherein the at least one hybrid bonded electrically conductive structure comprises a first electrically conductive structure and a second electrically conductive structure, wherein a hybrid bonding interface is located between the first electrically conductive structure and the second electrically conductive structure.

12. The structure of claim 1, wherein the thermal conductive material containing region comprises a first thermal conductive material containing portion composed of aluminum nitride (AlN) and a second thermal conductive material containing portion composed of AlN.

13. A structure comprising:
a hybrid bonding area located above a frontside BEOL structure, wherein the hybrid bonding area comprises a hybrid bonding interface located between a first bonding dielectric material containing portion and a second bonding dielectric material containing portion, and between a first thermal and electrically conductive cap of a first thermal conductive material containing portion a second thermal and electrically conductive cap of a second thermal conductive material containing portion.

14. The structure of claim 13, wherein the first bonding dielectric material containing portion and the second bonding dielectric material containing portion are composed of a bonding dielectric material.

15. The structure of claim 13, wherein the first thermal and electrically conductive cap and the second thermal and electrically conductive cap are composed of a thermal and electrically conductive material.

16. The structure of claim 13, further comprising a first thermal conductive material containing base in contact with a surface of the first thermal and electrically conductive cap, and a second thermal conductive material containing base in contact with a surface of the second thermal and electrically conductive cap.

17. The structure of claim 16, wherein the first thermal conductive material containing base and the second thermal conductive material containing base are composed of AlN.

18. The structure of claim 13, further comprising a device layer comprises one or more semiconductor devices located beneath the frontside BEOL structure.

19. The structure of claim 18, further comprising a backside BEOL structure located beneath the device layer.

20. The structure of claim 13, wherein a dielectric-to-dielectric bond is present at the hybrid bonding interface between the first bonding dielectric material containing portion and the second bonding dielectric material containing portion, and a metal-to-metal bond is present at the hybrid bonding interface between the first thermal and electrically conductive cap and the second thermal and electrically conductive cap.
